(19) United States
(12) Patent Application Publication
(10) Pub. No.: US 2026/0334208 A1
(43) Pub. Date: Oct. 22, 2026

(54) SEMICONDUCTOR STRUCTURE

(71) Applicant: Winbond Electronics Corp., Taichung City (TW)

(72) Inventors: Lun-Lun CHEN, Taichung City (TW); Kao-Tsair TSAI, Taichung City (TW); Chang-Ju HO, Taichung City (TW)

(21) Appl. No.: 19/442,263

(22) Filed: Jan. 7, 2026

(30) Foreign Application Priority Data
Apr. 16, 2025 (TW) 114114301

(51) Int. Cl. H10W 20/43; H10W 10/17; H10W 20/42

(52) U.S. Cl. CPC H10W 20/43; H10W 10/17; H10W 20/422

(57) ABSTRACT

A semiconductor structure includes a substrate with an array region and a periphery region surrounding the array region. The substrate includes a plurality of active regions in the array region. The active regions extend in a first direction, and they are arranged in a second direction. The memory device includes a plurality of word line structures disposed over the substrate and in the array region. The word line structures extend in the second direction and are arranged in the first direction. The memory device further includes a plurality of contact structures disposed on the active regions and between the word line structures. The contact structures include a first contact closest to the periphery region and a second contact adjacent to the first contact. The first width of the first contact in the second direction is greater than the second width of the second contact in the second direction.

### CROSS REFERENCE TO RELATED APPLICATIONS

This application claims priority of Taiwan patent application No. 114114301, filed Apr. 16, 2025, the entirety of which is incorporated by reference herein.

### TECHNICAL FIELD

The present disclosure relates to semiconductor technology, and, in particular, to a contact structure of a flash memory device.

### BACKGROUND

In order to increase device density within a flash memory device and to improve its overall performance, current manufacturing technologies for flash memory devices have been consistently advancing towards further device scaling. However, as the device dimensions continue to decrease, various challenges arise. For example, the contact structures located at the edge of the array region may have incomplete structures due to etching loading effects (for example, the contact structures may have a smaller contact area), which increases the current density of the contact structures to an undesirable level, and which adversely affects the electrical performance of the flash memory device. Therefore, there is a need in the industry to improve the methods of manufacturing flash memory devices so as to overcome the issues caused by device scaling.

### BRIEF SUMMARY

The embodiment of the present disclosure provides a semiconductor structure, including a substrate with an array region and a periphery region surrounding the array region. The substrate includes a plurality of active regions in the array region, and the active regions extend in a first direction and are arranged in a second direction. The semiconductor structure further includes a plurality of word line structures disposed over the substrate and in the array region. The word line structures extend in the second direction and are arranged in the first direction. The semiconductor structure further includes a plurality of contact structures disposed on the active regions and between the word line structures. The contact structures include a first contact closest to the periphery region and a second contact adjacent to the first contact. The first width of the first contact in the second direction is greater than the second width of the second contact in the second direction.

In some embodiments, the first width of the first contact is greater than twice the second width of the second contact. In some embodiments, the first width of the first contact is not greater than three times the second width of the second contact. In some embodiments, the second width of the second contact is equal to the spacing between the contact structures in the second direction. In some embodiments, the second width of the second contact is equal to the width of the active regions in the second direction. In some embodiments, the contact structures are arranged along the second direction. In some embodiments, the spacing between the contact structures in the second direction is equal to the spacing between the active regions in the second direction. In some embodiments, the ratio of the first width of the first contact to the second width of the second contact is 2.5:1. In some embodiments, the boundary of the first contact in the second direction extends a first distance beyond the boundary of one of the active regions that corresponds to the first contact. In some embodiments, the first distance is greater than the spacing between the active regions in the second direction. In some embodiments, the first distance is greater than the spacing between the contact structures in the second direction. In some embodiments, the ratio of the first distance to the spacing between the contact structures in the second direction is 1.5:1. In some embodiments, in a cross-sectional view, the projected area of the first contact on the substrate is greater than the projected area of the second contact on the substrate. In some embodiments, in a cross-sectional view, the projected area of the first contact on the substrate is greater than the projected area of one of the active regions corresponding to the first contact on the substrate. In some embodiments, a distance between the first contact and the periphery region is within a range of 0.26 μm to 0.3 μm. In some embodiments, a distance between the first contact and the word line structures in the first direction is within a range of 0.1 μm to 0.12 μm. In some embodiments, in a cross-sectional view, the bottom width of the first contact is greater than the bottom width of the second contact. In some embodiments, in a cross-sectional view, the bottom width of the first contact is greater than the top width of one of the active regions corresponding to the first contact. In some embodiments, the ratio of the bottom width of the first contact to the top width of one of the active regions corresponding to the first contact is 1.4:1. In some embodiments, the ratio of the bottom width of the first contact to the bottom width of the second contact is 1.4:1.

### BRIEF DESCRIPTION OF THE DRAWINGS

FIG. 1 illustrates a top view of the semiconductor structure according to the embodiments of the present disclosure.

FIG. 2 illustrates a fragmental top view of the semiconductor structure according to the embodiments of the present disclosure.

FIGS. 3, 4, and 5 illustrate fragmental top views of the semiconductor structure according to the embodiments of the present disclosure.

FIG. 6 illustrates a cross-sectional view of the semiconductor structure according to the embodiments of the present disclosure.

### DETAILED DESCRIPTION

In the embodiments of the present disclosure, by modifying the pattern design of specific contact structures, the contact structures affected by etching loading effects may have larger and more stable structures, thereby preventing adverse impacts on current density and maintaining the yield of the flash memory device.

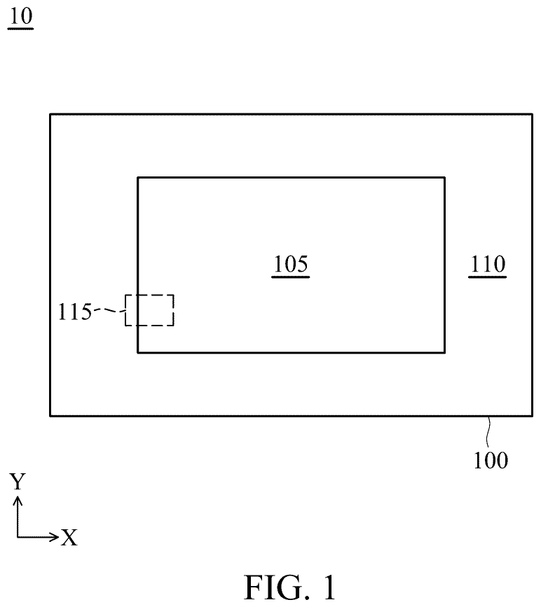

Referring to FIG. 1, a semiconductor structure 10 may be a flash memory device. In some embodiments, the semiconductor structure 10 includes a substrate 100. The substrate 100 has an array region 105 and a periphery region 110 surrounding the array region 105. In some embodiments, the substrate 100 may be an elemental semiconductor substrate, a compound semiconductor substrate, or an alloy semiconductor substrate. In other embodiments, the substrate 100 may be a semiconductor-on-insulator (SOI) substrate.

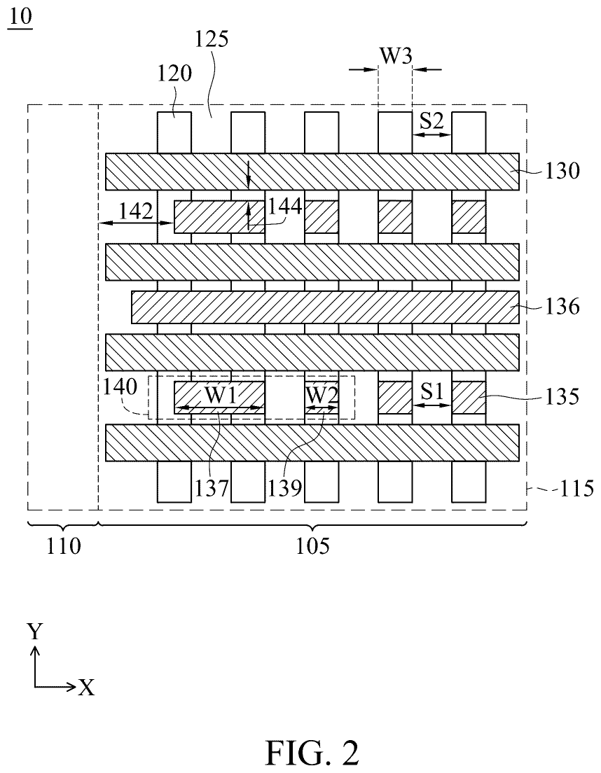

Referring next to FIG. 2, FIG. 2 illustrates a fragmental top view of a portion of block 115 in FIG. 1. In some embodiments, the substrate 100 includes a plurality of active regions 120 in the array region 105. In some embodiments, the active regions 120 may be separated and defined by isolation structures 125. The active regions 120 extend along a first direction (for example, the Y direction) and are arranged in a second direction (for example, the X direction). The positions of the active regions 120 may overlap with bit line structures, which are not separately illustrated for simplicity. In some embodiments, the first direction and the second direction intersect with each other, for example, the first direction is perpendicular to the second direction. In some embodiments, the isolation structures 125 may include an insulating material, such as silicon oxide. In some embodiments, the isolation structures 125 may include shallow trench isolation (STI) structures.

Continuing with FIG. 2, in some embodiments, the substrate 100 includes a plurality of word line structures 130 disposed over the substrate 100 and located in the array region 105. In some embodiments, the word line structures 130 extend along the second direction (for example, the X direction) and are arranged along the first direction (for example, the Y direction). In some embodiments, the word line structures 130 may include stacked films along a third direction (for example, the Z direction). In some embodiments, the third direction intersects with both the first direction and the second direction, for example, the third direction is perpendicular to the first direction and the second direction.

Continuing with FIG. 2, in some embodiments, the substrate 100 includes a plurality of contact structures 135 disposed on the active regions 120 and between the word line structures 130. In some embodiments, the contact structures 135 are arranged along the second direction (for example, the X direction). The contact structures 135 include a first contact 137 closest to the periphery region 110 and a second contact 139 adjacent to the first contact 137. In some embodiments, the contact structures 135 may be self-aligned contacts (SACs). For example, a self-aligned contact may be formed by patterning an interlayer dielectric layer using photolithography and etching processes in conjunction with a contact etch stop layer. In some embodiments, the first width W1 of the first contact 137 in the second direction (for example, the X direction) is greater than the second width W2 of the second contact 139 in the second direction. Additionally, in some embodiments, the contact structures 135 further include a bar-shaped contact 136 extending along the second direction (for example, the X direction).

Due to the boundary definition of the periphery region 110 and the etching loading effects, the first contact 137 located at the edge of the array region 105 may have an incomplete structure. For example, due to incomplete etching of the contact openings, the first contact 137 at the edge of the array region 105 may have a smaller contact area with the active region 120 compared to the contact structures 135 (located in the central portion of the array region 105) that are fully etched. The smaller contact area between the first contact 137 and the active region 120 may undesirably affect current density and further degrade the electrical performance of the flash memory device. In the present disclosure, by designing the first width W1 of the first contact 137 to be greater than the second width W2 of the second contact 139 (and the other contact structures 135), sufficient contact area between the first contact 137 and the active region 120 may be ensured, thereby preventing an increase in current density. Furthermore, the design of the first contact 137 may be readily integrated into existing process technologies.

In some embodiments, the first width W1 is greater than twice the second width W2. In some embodiments, the first width W1 is not greater than three times the second width W2. In other words, the first width W1 ranges between twice and three times the second width W2. In some embodiments, the ratio of the first width W1 to the second width W2 is 2.5:1, thereby ensuring sufficient contact area between the first contact 137 and the active region 120. In some embodiments, the second width W2 is equal to the spacing S1 between the contact structures 135 in the second direction (for example, the X direction). In some embodiments, the second width W2 of the second contact 139 is equal to the width W3 of the active regions 120 in the second direction (for example, the X direction). In some embodiments, the spacing S1 between the contact structures 135 in the second direction (for example, the X direction) is equal to the spacing S2 between the active regions 120 in the second direction (for example, the X direction). In some embodiments, a distance 142 between the first contact 137 and the periphery region 110 is within a range of about 0.26 μm to about 0.3 μm. In some embodiments, a distance 144 between the first contact 137 and the word line structures 130 in the first direction (for example, the Y direction) is within a range of about 0.1 μm to about 0.12 μm.

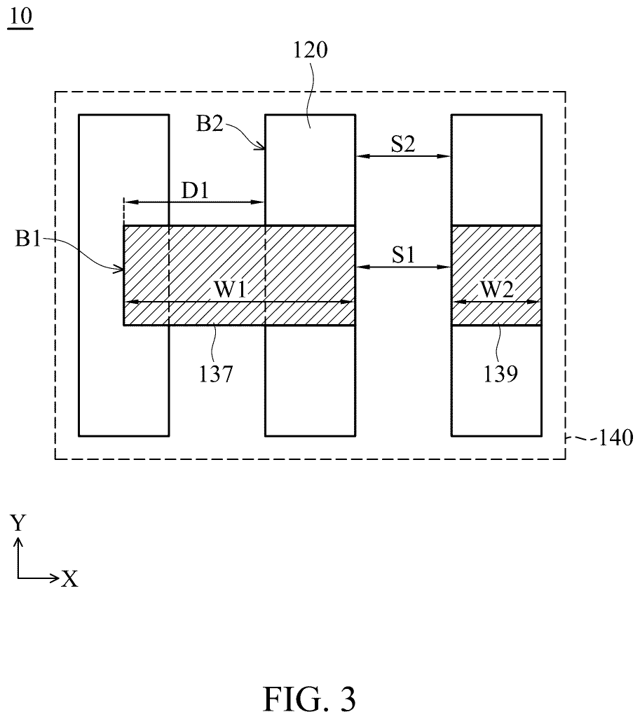

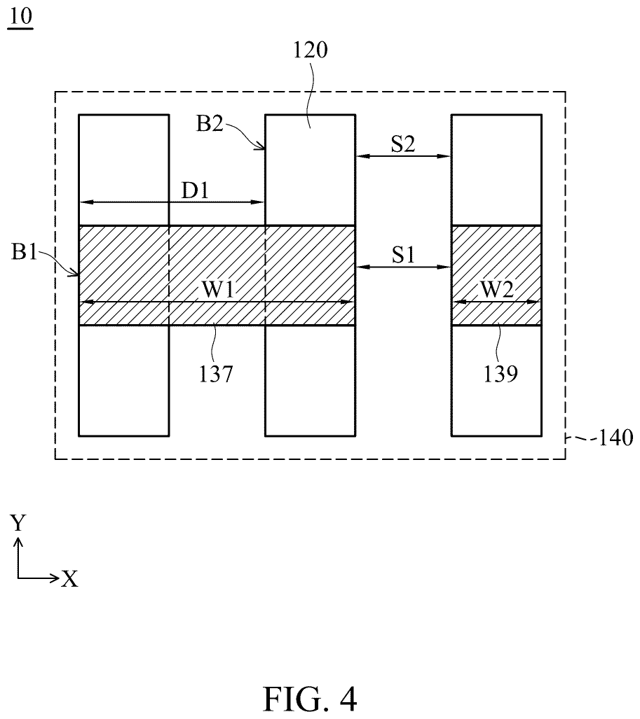

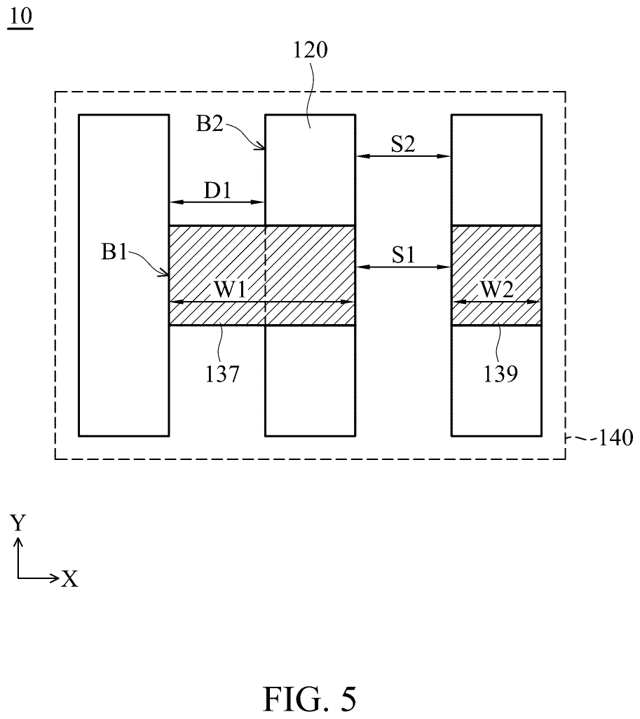

Next, referring to FIGS. 3, 4, and 5, FIGS. 3, 4, and 5 illustrate fragmental top views of the semiconductor structure 10 according to the embodiments of the present disclosure. More specifically, FIGS. 3, 4, and 5 illustrate fragmental top views of a portion of a block 140 in FIG. 2. In some embodiments, FIG. 3 illustrates an embodiment in which the ratio of the first width W1 to the second width W2 is 2.5:1. In some embodiments, FIG. 4 illustrates an embodiment in which the ratio of the first width W1 to the second width W2 is 3:1. In some embodiments, FIG. 5 illustrates an embodiment in which the ratio of the first width W1 to the second width W2 is 2:1.

In some embodiments, as illustrated in FIGS. 3, 4, and 5, the boundary B1 of the first contact 137 extends a first distance D1 in the second direction (for example, the X direction) beyond the boundary B2 of one of the active regions 120 that corresponds to the first contact 137. In some embodiments, the first distance D1 is greater than the spacing S2 between the active regions 120 in the second direction (for example, the X direction). In some embodiments, the first distance D1 is greater than the spacing S1 between the contact structures 135 in the second direction (for example, the X direction). In some embodiments, as shown in FIG. 3, the ratio of the first distance D1 to the spacing S1 between the contact structures 135 in the second direction (for example, the X direction) is 1.5:1. In some embodiments, as shown in FIG. 4, the ratio of the first distance D1 to the spacing S1 between the contact structures 135 in the second direction (for example, the X direction) is 2:1. In some embodiments, as shown in FIG. 5, the ratio of the first distance D1 to the spacing S1 between the contact structures 135 in the second direction (for example, the X direction) is 1:1.

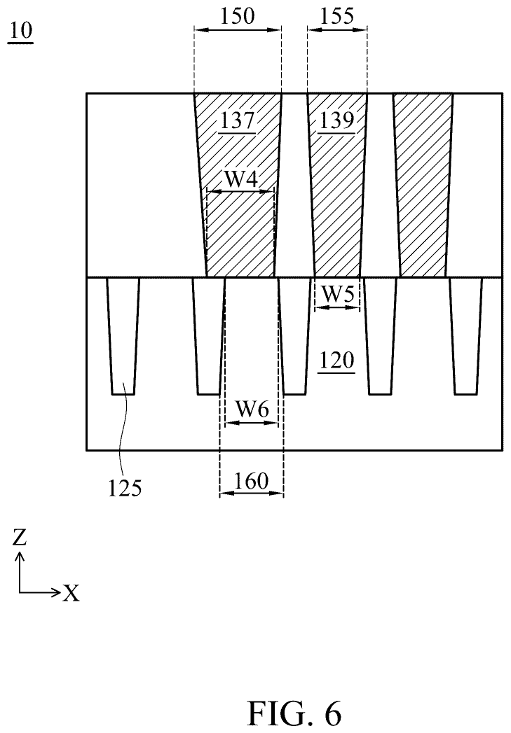

Referring next to FIG. 6, FIG. 6 illustrates a cross-sectional view of the semiconductor structure 10 according to the embodiments of the present disclosure. More specifically, FIG. 6 illustrates a cross-sectional view of the first contact 137, the second contact 139, and the active regions 120. In some embodiments, in FIG. 6, the projected area 150 of the first contact 137 on the substrate 100 is greater than the projected area 155 of the second contact 139 on the substrate 100. In some embodiments, in FIG. 6, the projected area 150 of the first contact 137 on the substrate 100 is greater than the projected area 160 of one of the active regions 120 corresponding to the first contact 137 on the substrate 100. In some embodiments, in FIG. 6, the bottom width W4 of the first contact 137 is greater than the bottom width W5 of the second contact 139. In some embodiments, in FIG. 6, the bottom width W4 of the first contact 137 is greater than the top width W6 of one of the active regions 120 corresponding to the first contact 137. In some embodiments, the ratio of the bottom width W4 of the first contact 137 to the top width W6 of one of the active regions 120 corresponding to the first contact 137 is 1.4:1. In some embodiments, the ratio of the bottom width W4 of the first contact 137 to the bottom width W5 of the second contact 139 is 1.4:1.

In summary, in the embodiments of the present disclosure, by modifying the pattern design of specific contact structures, the contact structures affected by etching loading effects may have larger and more stable structures, thereby preventing adverse impacts on current density and maintaining the yield of the flash memory device. More specifically, by designing the first width of the first contact closest to the periphery region to be greater than the second width of the adjacent second contact (and the other contact structures), sufficient contact area between the first contact and the active region may be ensured, thereby preventing an increase in current density. Furthermore, the design of the first contact may be readily integrated into existing process technologies. It should be understood that not all advantages are necessarily discussed herein, nor are all embodiments required specific advantages, and other embodiments may provide different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate with an array region and a periphery region surrounding the array region, wherein the substrate comprises a plurality of active regions in the array region, and wherein the active regions extend in a first direction and are arranged in a second direction;
a plurality of word line structures disposed over the substrate and in the array region, wherein the word line structures extend in the second direction and are arranged in the first direction; and
a plurality of contact structures disposed on the active regions and between the word line structures,
wherein the contact structures comprise a first contact closest to the periphery region and a second contact adjacent to the first contact,
wherein a first width of the first contact in the second direction is greater than a second width of the second contact in the second direction.

2. The semiconductor structure as claimed in claim 1, wherein the first width is greater than twice the second width.

3. The semiconductor structure as claimed in claim 1, wherein the first width is not greater than three times the second width.

4. The semiconductor structure as claimed in claim 1, wherein the second width is equal to a spacing between the contact structures in the second direction.

5. The semiconductor structure as claimed in claim 1, wherein the second width is equal to a width of the active regions in the second direction.

6. The semiconductor structure as claimed in claim 1, wherein the contact structures are arranged along the second direction.

7. The semiconductor structure as claimed in claim 1, wherein a spacing between the contact structures in the second direction is equal to a spacing between the active regions in the second direction.

8. The semiconductor structure as claimed in claim 1, wherein a ratio of the first width to the second width is 2.5:1.

9. The semiconductor structure as claimed in claim 1, wherein a boundary of the first contact in the second direction extends a first distance beyond a boundary of one of the active regions corresponding to the first contact.

10. The semiconductor structure as claimed in claim 9, wherein the first distance is greater than a spacing between the active regions in the second direction.

11. The semiconductor structure as claimed in claim 9, wherein the first distance is greater than a spacing between the contact structures in the second direction.

12. The semiconductor structure as claimed in claim 9, wherein a ratio of the first distance to a spacing between the contact structures in the second direction is 1.5:1.

13. The semiconductor structure as claimed in claim 1, wherein in a cross-sectional view, a projected area of the first contact on the substrate is greater than a projected area of the second contact on the substrate.

14. The semiconductor structure as claimed in claim 1, wherein in a cross-sectional view, a projected area of the first contact on the substrate is greater than a projected area of one of the active regions corresponding to the first contact on the substrate.

15. The semiconductor structure as claimed in claim 1, wherein a distance between the first contact and the periphery region is within a range of 0.26 μm to 0.3 μm.

16. The semiconductor structure as claimed in claim 1, wherein a distance between the first contact and the word line structures in the first direction is within a range of 0.1 μm to 0.12 μm.

17. The semiconductor structure as claimed in claim 1, wherein in a cross-sectional view, a bottom width of the first contact is greater than a bottom width of the second contact.

18. The semiconductor structure as claimed in claim 1, wherein in a cross-sectional view, a bottom width of the first contact is greater than a top width of one of the active regions corresponding to the first contact.

19. The semiconductor structure as claimed in claim 1, wherein a ratio of a bottom width of the first contact to a top width of one of the active regions corresponding to the first contact is 1.4:1.

20. The semiconductor structure as claimed in claim 1, wherein a ratio of a bottom width of the first contact to a bottom width of the second contact is 1.4:1.
